(19) United States
(12) Patent Application Publication
(10) Pub. No.: US 2025/0274093 A1
(43) Pub. Date: Aug. 28, 2025

(54) METHOD AND APPARATUS FOR REMOVING DC OFFSET FROM A SIGNAL

(71) Applicant: Analog Devices International Unlimited Company, Limerick (IE)

(72) Inventors: Patrick Pratt, Mallow (IE); Philip Eugene Quinlan, Glounthaune (IE)

(21) Appl. No.: 19/042,965

(22) Filed: Jan. 31, 2025

Related U.S. Application Data
(60) Provisional application No. 63/556,678, filed on Feb. 22, 2024.

(51) Int. Cl. H03H 7/01; H03H 17/02

(52) U.S. Cl. CPC H03H 7/0153; H03H 17/0294

(57) ABSTRACT

There are provided methods and apparatuses for removing a DC offset from an input signal, comprising: receiving the input signal having a first phase and a second phase; applying a high pass filter to the input signal, wherein a transfer function of the high pass filter has a pole coefficient that determines a pole frequency of the high pass filter, comprising: selecting a first pole coefficient of the high pass filter for the first phase, estimating DC offset of the input signal during the first phase, and selecting a second pole coefficient of the high pass filter for the second phase, wherein the first pole coefficient and the second pole coefficient are selected such that the first pole frequency is higher than the second pole frequency; and removing the DC offset from the input signal.

### CLAIM OF PRIORITY

This application is a U.S. Non-Provisional application which claims priority to U.S. Provisional Application No. 63/556,678, filed Feb. 22, 2024, which is hereby incorporated by reference herein in its entirety.

### FIELD

This application relates generally to methods and apparatuses for removing DC offsets from a signal and, in particular but not exclusively, to methods and apparatus for removing DC offsets from a signal by using a high pass filter.

### BACKGROUND

In signal processing, a DC offset refers to a mean value of a signal waveform over time. When the mean value of the signal waveform is zero, then there is no DC offset. However, when the mean value of the signal waveform is a value other than zero, a DC offset exists and the mean value of the signal waveform is shifted above or below zero. Typically, DC offset voltages may be caused by integrated circuit manufacturing tolerances and imperfections that result in device mismatches in analog circuit design components such as resistors, capacitors, and transistors. This may lead to unwanted distortion in the signal waveform, and it may be determinantal in degrading the performance of the system.

DC offset correction can be a solution for removing DC offset errors in various applications, including communication systems. High pass filters are often used in signal processing for removing unwanted DC offsets. They allow for frequencies above a certain cutoff frequency to pass through while attenuating frequencies below the cutoff frequency.

However, when an input signal arrives at the input of a high-pass filter, it can take a long time for the high pass filter output to reach a steady state and sometimes the DC offset does not converge within a suitable time period. For some applications, a faster response is required such that the DC offset can be removed within a predetermined time period.

Therefore, it can be desirable to provide an improved solution for removing DC offsets from a signal.

### SUMMARY OF THE DISCLOSURE

The systems and methods of the present disclosure provide ways in which to remove DC offsets from a signal by using a high pass filter.

In one aspect of the present disclosure, there is provided a method of removing a DC offset from an input signal, the method comprising: receiving the input signal having a first phase and a second phase; applying a high pass filter to the input signal, wherein a transfer function of the high pass filter has a pole coefficient that determines a pole frequency of the high pass filter, comprising: selecting a first pole coefficient of the high pass filter for the first phase, estimating DC offset of the input signal during the first phase, and selecting a second pole coefficient of the high pass filter for the second phase, wherein the first pole coefficient and the second pole coefficient are selected such that the first pole frequency is higher than the second pole frequency; and removing the DC offset from the input signal.

The input signal can be an input signal to a high pass filter. The input signal may be but is not necessarily an input signal to the entire signal chain.

The input signal may be a real signal or a complex signal. The input signal may be an analog signal or a digital signal. The input signal may comprise an in-phase, I, component and a quadrature, Q, component.

High pass filtering may be performed in the digital domain or in the analog domain. In either case, a pole coefficient of the high pass filter may be selected for different phases of the input signal. A first pole coefficient of the high pass filter is selected for the first phase, and a second pole coefficient of the high pass filter is selected for the second phase. The first pole coefficient and the second pole coefficient are selected such that the first pole frequency is higher than the second pole frequency; and removing the DC offset from the input signal.

The process of selecting the first and second pole coefficients involves determining the appropriate cutoff frequencies for each phase. The first pole coefficient is chosen to set a higher cutoff frequency during the first phase, allowing for quick estimation of the DC offset. The second pole coefficient is selected for a lower cutoff frequency during the second phase, ensuring more accurate DC offset removal over a longer period of time.

In general, the method of the present disclosure may apply to systems for which having a slow transient response in order to remove the DC offset component are unacceptable. In one example, the method may be used in context of radio transmitters and receiver, for removing a DC offset from a transmitted signal at the receiver. The first phase may be a preamble phase, a header phase or a calibration phase. The second phase may be a payload phase. In this example, the pole coefficient selected for a preamble phase and the payload phase may be such that the pole frequency for the preamble phase is higher than the pole frequency for the payload phase. In this example, high pass filtering using different pole frequencies for different phases of the input signal can balance the effective removal of DC content and low-frequency signal content for the preamble phase whilst minimizing transient time in order to preserve the transmitted signal in the payload phase. However, the present disclosure does not only apply to communications systems. It may also apply to any signal processing path for which removing a DC offset from an input signal is desired. In some other examples, the method may be used in context of power constrained and/or latency constrained signal chains. In a battery powered remote sensing system that periodically turns on to sense some quantity (e.g., temperature, humidity, etc.), the analog-front-end circuitry may suffer from a DC offset that must be first removed before the quantity is sensed. However, it is desirable to remove the DC offset in a time-critical fashion, and preferably to a defined level of accuracy, so that the power in the battery is not unduly wasted. If a fixed pole high pass filter cannot meet this requirement, then a dynamically adjusted pole high pass filter would be an advantageous solution. In yet another example, it may be beneficial to reduce system latency in a signal chain. In this use case, a preamble may be appended to the beginning of a transmitted data payload to allow sufficient time for DC offset correction to be carried out in a receiver. To minimise system latency (Tx to Rx time delay) and to maximise data throughput in the communication data link, it is highly desirable to minimise the allocated time duration of the preamble header in the transmitted packet. (i.e. the preamble is an undesirable overhead and does not carry any information from Tx to Rx). This results in the need for a high-pass filter that removes DC offset in a time-bounded fashion in the receiver.

In general, in any application where it is desirable to remove DC offset in a time-bounded fashion to a defined level of accuracy, where a fixed pole high pass filter does not offer the flexibility required, then a high pass filter having at least two pole coefficients according to the present disclosure may be advantageous.

Removing the DC offset from the input signal may be done using feedforward techniques, feedback techniques, or a combination of feedforward and feedback techniques.

The method may further comprise using a look up table to select the pole coefficient of the high pass filter.

In some examples, using a look up table to determine the pole coefficient of the high pass filter may comprise selecting the pole coefficient based on a time parameter. Therefore, an input to the look up table may be a time parameter and an output of the look up table may be a pole coefficient. The time parameter may be a time instant, a time index or a time interval.

The pole coefficient may have a value between 0 and 1, for example, the real part may be between 0 and 1 when the high pass filter is a discrete filter. In an example, this may be expressed alternatively as the bandwidth of the high pass filter having a normalised scaling coefficient between 0 and 1. As the pole coefficient tends towards 0, the filter may pass more and more signal until everything with no time lag, i.e. there is no low pass filtering and the signal passes through the filter unaltered. As the pole coefficient tends towards 1, the filter may attenuate more and more signal until it attenuates everything, i.e. all of the signal content is attenuated, except DC, but the filter takes infinity to settled. In the case of a first order (single pole) IIR filter, when the pole coefficient is 0, the bandwidth of the high pass filter is at its widest, and when the pole coefficient is 1, the bandwidth of the high pass filter tends towards 0.

In some examples, the first phase comprises a predetermined duration, and selecting the first pole coefficient for the first phase comprises selecting the first pole coefficient such that estimating the DC offset is completed within the predetermined duration.

In some examples, the predetermined duration comprises a predetermined number of symbols. A symbol in this context refers to a unit of data in the signal, which could represent a bit, a group of bits, or another data unit depending on the signal, communication, or information processing protocol.

The method may comprise determining a phase of the input signal. This may include determining whether the input signal is in the first phase or the second phase. Further, this may include determining a sub-phase of the input signal.

In some examples, the method further comprises dynamically adjusting the pole coefficient of the high pass filter using the look-up table. Advantageously, depending upon which phase or sub-phase of the input signal is in, the pole coefficient selected for the high pass filter may vary. This means that a pole coefficient that is most suitable for each phase or sub-phase of the input signal may be selected.

In some examples, the method further comprises dynamically adjusting the pole coefficient from the first pole coefficient to the second pole coefficient. This may be, for example, it is determined that the input signal has changed from being in the first phase to being in the second phase.

In some examples, the method further comprises dynamically adjusting the first pole coefficient so as to decrease the pole frequency during the first phase. In some examples, dynamically adjusting the first pole coefficient comprises dynamically lowering the first pole coefficient with respect to time in any one of many functional manners (exponentially, logarithmically, etc.)

In some examples, the method further comprises dynamically adjusting the second pole coefficient so as to decrease the pole frequency during the second phase. In some examples, dynamically adjusting the second pole coefficient comprises dynamically lowering the second pole coefficient with respect to time in any one of many functional manners (exponentially, logarithmically, etc.).

In some examples, the method further comprises using at least one of a state machine, a logic sequencer, a timing controller and a systems controller to control the selection of the pole coefficient.

In the case of a state machine, the state machine may transition between states based on a characteristic on the input signal, such as detecting the end of the first phase and the beginning of the second phase. The state machine may comprise one or more states per phase of the input signal. Each state of the state machine may correspond to a specific pole coefficient selection, ensuring the correct coefficient is applied at the right time.

In the case of a logic sequencer, the logic sequencer may control a sequence of operations, ensuring that the pole coefficients are selected in the correct order. It can be programmed to follow a specific sequence of steps, such as selecting the first pole coefficient for the first phase of the input signal, and then selecting the second pole coefficient for the second phase of the input signal.

In the case example of a timing controller, the timer controller may be used to manage the timing of the pole coefficient selection. It can ensure that the first pole coefficient is applied for a specific duration for the first phase of the input signal, and then switch to the second pole coefficient for the second phase. The second pole coefficient may also be applied for a specific duration. This is particularly useful if the phases of the input signal are determined based on a time parameter.

In the case of a systems controller, the systems controller may manage the overall process of selecting pole coefficients for the high pass filter. It can integrate various inputs and control signals to ensure the correct coefficients are applied during each phase of in the input signal. For example, it can monitor the input signal to continuously analyse the input signal in order to determine the appropriate timing for switching between the first and second phases. Further, it can manage the transition between the first and second phases, ensuring the correct pole coefficient is selected for each phase, such as applying the first pole coefficient during the first phase and switching to the second pole coefficient during the second phase. Yet further, it can dynamically adjust the pole coefficients based on real time feedback from the input signal, thus optimizing the performance of the high pass filter and ensuring effective DC offset removal.

In some examples, estimating the DC offset comprises low pass filtering the input signal, and the method further comprises removing the DC offset from the input signal by subtracting the estimated DC offset from the input signal.

In some examples, the method further comprises using a feedback loop to update the estimated DC offset based on a pole coefficient of the high pass filter.

In some examples, an output signal of the high pass filter is a difference between the input signal and a previous input signal minus the pole coefficient multiplied by a previous output signal.

In some examples, selecting a first pole coefficient comprises selecting a first pole coefficient such that a first pole frequency is between 1 MHz and 10 kHz. Further, the method may comprises selecting one or more pole coefficients such that pole frequencies in the first phase are between 1 MHz and 10 kHz.

In some examples, selecting a second pole coefficient comprises selecting a second pole coefficient such that the second pole frequency is between 1 kHz and 100 Hz Further, the method may comprises selecting one or more pole coefficients such that pole frequencies in the second phase are between 1 kHz and 100 Hz.

In another aspect of the present disclosure, there is provided an apparatus for removing a DC offset from an input signal, the apparatus comprising: a high pass filter, configured to: receive an input signal having a first phase and a second phase; apply a high pass filter to the input signal, wherein a transfer function of the high pass filter has a pole coefficient that determines a pole frequency of the high pass filter, comprising: selecting a first pole coefficient of the high pass filter for the preamble phase, estimating DC offset of the input signal during the first phase, and selecting a second pole coefficient of the high pass filter for the second phase, wherein the first pole coefficient and the second pole coefficient are selected such that the first pole frequency is higher than the second pole frequency; and remove the DC offset from the input signal.

The high pass filter may have a time varying pole frequency. This means that the cutoff frequency of the filter may change over time, which can be particularly useful in applications where the characteristics of the input signal change dynamically. By adjusting the pole frequency, the high pass filter can adapt to different signal conditions, improving the accuracy of DC offset removal during different phases of the input signal.

The high pass filter may be implemented as an analog filter (typically with resistors and capacitors) or as a digital filter (typically as an infinite impulse response filter (IIR) or as a finite impulse response filter (FIR)).

The high pass filter may be a first order high pass filter or a higher order high pass filter. A first order high pass filter may be defined as having a single reactive component (for example, a capacitor or inductor) and a resistor. Alternatively, a first order high pass filter may be defined by having one pole. It may provide a slope of, for example, 20 dB/decade (or 6 db/octave) in its frequency response. It is simpler and easier to implement than a higher order high pass filter but it may not provide sufficient attenuation for some applications. A higher order high pass filter use multiple reactive components and resistors, resulting in a steeper slope, for example, 40 dB/decade for a second-order filter. A higher order high pass filter may have a higher number of poles. A higher order filters can provide better performance in terms of attenuation and phase response, making them suitable for more demanding applications, for which high precision measurements and minimal distortion are required, such as communication systems, medical instrumentation, and industrial automation.

The high pass filter may comprise a differentiator and a low pass filter. In this example, the differentiator and low pass filter may combine to provide a high pass filtering action, via: the LPF estimates the DC, while the differentiation acts to subtract out or remove this estimate from the signal.

In an alternative example to the differentiator and low pass filter, the high pass filter may comprise a leaky integrator. In this example, a leaky integrator may be simpler to implement than the differentiator and low pass filter, and provides greater stability with less sensitivity to high-frequency noise.

Estimating DC offset may be performed by a DC estimator. For example, the DC estimator may be a IIR filter having one pole coefficient per phase. In another example, the DC estimator may be a FIR filter having a numerator transfer function only with no denominator or poles. Low pass filtering action is achieved by averaging the signal over an extended time horizon. This averaging window is controlled by the values and numbers of the numerator coefficients.

The apparatus may further comprise a memory device configured to store a look up table. An input to the look up table may comprise a time parameter and an output of the look up table comprises the pole coefficient.

The apparatus may further comprise at least one of a state machine, a logic sequencer, a timing controller and a systems controller.

In the case of a state machine, the state machine may be configured to generate a pulse indicating the start of the first phase and configured to generate a pulse indicating the start of the second phase. Additionally or alternatively, the state machine may be configured to generate a timeslot for the first phase and generate a timeslot for the second phase.

In the case of a logic sequencer, the logic sequencer may be configured to control a sequence of operations to ensure that the pole coefficients are selected in the correct order to correspond with a phase or sub-phase of the input signal.

In the case example of a timing controller, the timer controller may be configured to manage the timing of the pole coefficient selection to correspond with a time parameter of a phase or sub-phase of the input signal.

In the case of a systems controller, the systems controller may be configured to monitor the input signal to continuously analyse the input signal in order to determine the appropriate timing for switching between the first and second phases, manage the transition between the first and second phases and/or dynamically adjust the pole coefficients based on real time feedback from the input signal.

### Definitions

In many systems comprising a signal chain, a signal comprises a first phase and a second phase. For example, the first phase could be a preamble, a header or a calibration portion of the signal, which contains information for allowing signal chain to perform automatic gain control, DC offset correction, timing synchronization, or any other calibration. For example, the second phase could be a payload portion of the signal. In the case that the first phase is a preamble, this may be a sequence of bits or symbols that is transmitted at the beginning of a data packet, and it may be used to synchronize the received signal in terms of timing, frequency, phase etc. The preamble may be used in order to correct carrier frequency offset or to train a coefficient in an automatic gain control block, for example. In the case that the second phase is a payload, this may be the actual data being transmitted and it may contain text, images or other types of data representing the message.

A ‘high pass filter’ is an electronic component that allows signals with a frequency higher than a certain cutoff frequency to pass through and attenuates signals with frequencies lower than the cutoff frequency or corner frequency. High pass filters are typically used in communications systems such as audio processing to remove low-frequency noise, or in radio communications to block unwanted low-frequency signal, etc.

A ‘pole frequency’ of a high pass filter is the frequency at which the transfer function of the high pass filter becomes infinite or the frequency at which the transfer function denominator goes to zero. The pole frequency also equals a cutoff frequency of the high pass filter. The pole frequency may also between referred to as the −3 dB frequency, i.e., the frequency at which the transfer function of the high pass filter is −3 dB. There is a well-defined mathematical relationship between pole coefficients and the −3 dB pole frequency of an analog or digital high pass filter. Furthermore, some high pass filter designs might have multiple poles and/or multiple zeros that define the effective −3 dB frequency of the high pass filter.

A ‘pole coefficient’ determines the frequency response of the high pass filter and determines the pole frequency of the high pass filter. For a digital first order high pass filter, a high pole coefficient, for example, a pole coefficient that tends towards 1, corresponds with a ‘slow’ pole and wide bandwidth of the high pass filter, allowing the filter to pass a wider range of higher frequencies. Conversely, a low pole coefficient, for example, a pole coefficient that tends towards 0, corresponds with a ‘fast’ pole and narrow bandwidth of the high pass filter, allowing the filter to pass a narrow range of higher frequencies while attenuating higher frequencies more effectively.

### BRIEF DESCRIPTION OF THE DRAWINGS

Aspects of the present disclosure are described, by way of example only, with reference to the following drawings, in which:

FIG. 1 shows graphs illustrating DC offset estimation of a high pass filter;

FIG. 2 shows graphs illustrating DC offset estimation of a high pass filter;

FIG. 3 shows graphs illustrating DC offset estimation of a high pass filter;

FIG. 4 shows graphs comparing performance of a high pass filter for different cutoff frequencies;

FIG. 5 shows an example of an analog first order high pass filter;

FIG. 6 shows an example of a digital high pass filter;

FIG. 7 shows graphs illustrating characteristics of the high pass filters of FIGS. 5 and 6;

FIG. 8 shows a high pass filter that can be used in an apparatus in accordance with an example of the present disclosure;

FIG. 9 shows another high pass filter that can be used in an apparatus in accordance with an example of the present disclosure;

FIGS. 10a and 10b shows graphs illustrating characteristics of the high pass filters of FIGS. 8 and 9;

FIGS. 11a and 11b shows apparatuses in accordance with an example of the present disclosure;

FIG. 12 shows an apparatus in accordance with an example of the present disclosure;

FIG. 13 an implementation in accordance with an example of the present disclosure;

FIG. 14 shows an implementation in accordance with an example of the present disclosure;

FIGS. 15a and 15b show how a state machine that can be used in an apparatus in accordance with an example of the present disclosure; and

FIG. 16 represents example method steps according to an aspect of the present disclosure.

### DETAILED DESCRIPTION

A signal may have a wanted DC component and an unwanted DC component. Simple techniques for removing unwanted DC offsets from a signal using a fixed pole high pass filter. However, when an input signal arrives at the high pass filters input, these methods often have the disadvantage of not being fast enough to reach a steady state and sometimes the DC offset correction does not converge to the required value within the first phase.

As described in the background section, it is desirable to provide an improved solution for removing DC offsets from a signal using a high pass filter.

In some cases, systems having a slow transient response in order to remove the DC offset component are acceptable.

For example, in some audio applications, such as those operating between 0 Hz-20 kHz, it may be required to take out signal below 300 Hz and above 3 kHz using a bandpass filter. Such a system may typically settle in a few milliseconds without impacting upon the audio quality, i.e., the latency of the system is in the order of milliseconds, which is affordable because the human ear typically would not perceive such small delays. In another example, such as a front end of radio system that has automatic gain control, it is desired to amplify the AC part of the signal and not the DC. This may be done using a low noise amplifier. A slow transient response may be acceptable because the automatic gain controller can gradually adjust to changes in signal strength without significantly affecting the performance of the radio system. In cases such as this, for which the time to estimate and cancel the DC is not limited, a high pass filter having with a pole with a low frequency may be used in order to achieve the necessary DC correction accuracy.

However, in other cases, systems having a slow transient response in order to estimate the DC offset component are unacceptable.

For example, in the case of detection at the receiver end of a communication system, there is a need to correct DC offsets to much finer level in order to avoid degrading detection of the payload. In these cases, a slow transient response may lead to errors in detecting the payload, resulting in degraded performance of the detector and potential loss of data. In this case, a fast transient response is necessary to ensure accurate and reliable communication.

In another example, in the case of a battery powered system whereby energy conversative is critical, the battery powered system may have an array of sensors that measure a wide bandwidth analog signal near DC. For example, the wide bandwidth analog signal may be electrical power in an electrical network, temperature, altitude, or speed, etc. The array of sensors may have a duty cycle, for example, sensing once per minute or sensing once per day. The analog front end sensing circuit may have an unknown DC offset (e.g., varies with temperature, age, voltage supply) that is desired to be removed or reduced to a lower limit in a short period of time in order to minimize the battery energy consumption). Here, it is advantageous to reduce the DC offset in a time bounded manner without filtering out the wanted signal content near DC.

The present inventors have recognised that, for cases in which a fast transient response if required, a way in which to remove DC offsets from a signal using a high pass filter includes determining a cutoff frequency of the high pass filter that is low enough to remove the DC offset but high enough to preserve the integrity of the signal. This is done by using different pole frequencies that are suitable for each the first phase and the second phase of the signal. Since there may be no wanted DC component in the first phase, then a higher pole frequency or faster pole for the first phase provides the benefit of allowing DC estimation of the unwanted signal to be completed during the first phase, before a wanted DC component is present in the second phase. Essentially, the present inventors have come up with high pass filter that utilises a dynamic pole depending on a phase of the input signal, i.e. selecting different pole frequencies depending upon whether the input signal is in a first, second or subsequent phase of operation. Therefore, the high pass filter and associated methods for removing DC offsets from a signal using a high pass filter of the present disclosure may be described as time varying. The high pass filter and associated methods for removing DC offsets from a signal using a high pass filter of the present disclosure may substantially reduce the settling time of the high pass filters output, for example, compared to that of a fixed bandwidth high-pass filter.

Further, the present inventors have recognised that selecting different pole frequencies depending upon a sub-phase of the input signal may also be beneficial, i.e. the high pass filter and associated methods for removing DC offsets from a signal using a high pass filter of the present disclosure may be described as time varying within a phase. For example, dynamically monitoring a characteristic of the input signal may be used to determine which sub-phase it is in and adapting the pole coefficient accordingly in order to optimise removing unwanted DC offset while preserving the desired signal content. In another example, there may be other signals in the system that can be used to initiate bandwidth profile timing, such as a wake-up signal or a system timing reference signal or equivalent.

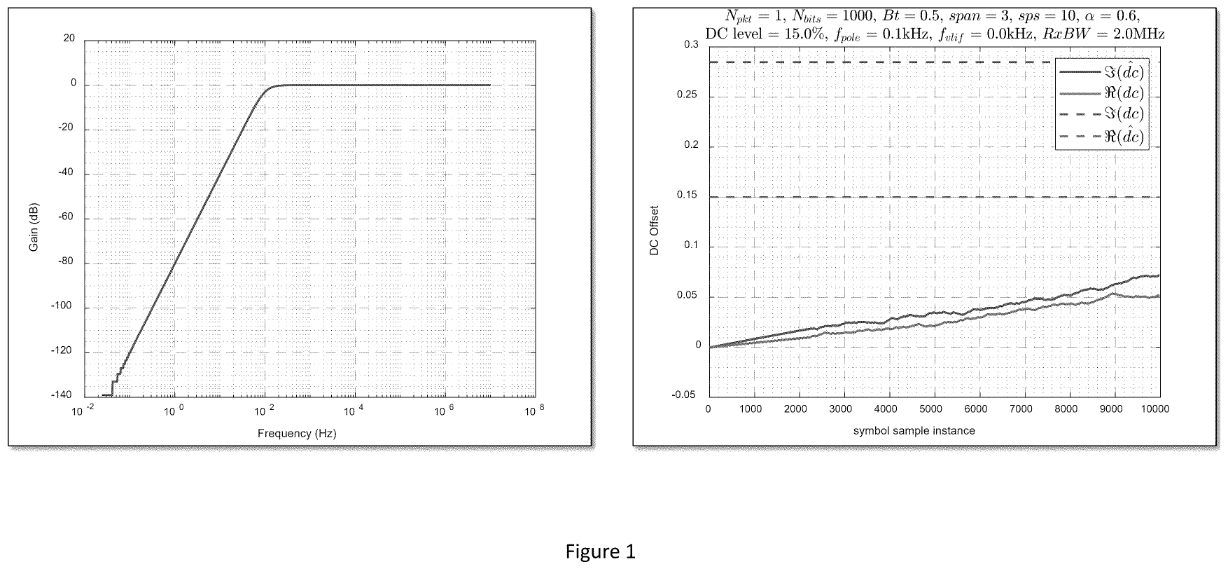

FIGS. 1, 2 and 3 illustrate how the cutoff frequency of a high pass filter can affect performance of a detector in terms of DC offset estimation whereby the input signal may be a signal transmitted by a transmitter and received at a receiver, the input signal having a preamble phase as its first phase and a payload phase as its second phase. The preamble phase may represent an initial transmission of a sequence of known bits. The payload phase may represent an actual payload of data. However, it will be appreciated that the methods and apparatuses of the present disclosure equally apply to other systems handling other types of input signal having a first phase and a second phase.

In each of FIGS. 1, 2 and 3, the dotted lines represent the actual DC offset of the in phase (I) component, i.e. the part of the signal that is in phase with the reference signal representing the real part of the signal, and the quadrature phase (Q) component, i.e. the part of the signal that is 90 degrees out of phase with the reference signal representing the imaginary part of the signal.

FIG. 1 shows graphs illustrating performance of a high pass filter having a cutoff frequency of 100 Hz.

In the graph of the left hand side, it is shown that the high pass filter has a frequency response which effectively attenuates low frequency signals, including DC components. At frequencies below 1 Hz, the attenuation reaches −100 dB, which is practically zero. As the frequency approaches 0 Hz, the attenuation becomes infinite, ensuring perfect DC offset removal. At 100 Hz, the attenuation is about −3 dB, marking the corner frequency of the high pass filter.

Turning to the graph on the right hand side, in the time domain, the high pass filter response is shown to be measured in symbols, with each symbol representing multiple digital samples. Initially, the high pass filter starts at 0 symbols. After 10,000 symbols, at the end of the first phase of the input signal. the response of the high pass filter approaches the actual DC value but has not fully settled. Over time, the response of the high pass filter will converge to the actual DC value, achieving perfect DC estimation. However, in this case, the pole frequency of 100 Hz means that the response of the high pass filter converges too slowly for an accurate DC estimate to be found within the first phase of the input signal.

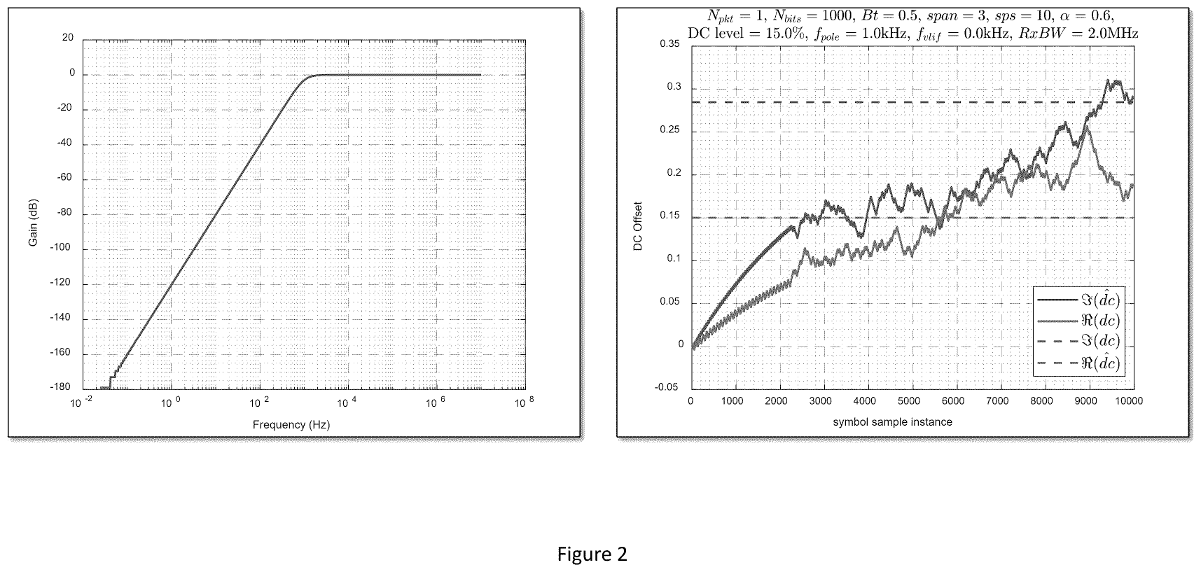

FIG. 2 shows graphs indicating performance of a high pass filter having a cutoff frequency of 1 kHz.

In the graph of the left hand side, it is shown that the high pass filter has a frequency response which effectively attenuates low frequency signals, including DC components. At frequencies below 10 Hz, the attenuation reaches −80 dB, which is practically zero. As the frequency approaches 0 Hz, the attenuation becomes infinite, ensuring perfect DC offset removal. At 1 kHz, the attenuation is about −3 dB, marking the corner frequency of the high pass filter.

Turning to the graph on the right hand side, it can be seen that when the pole frequency of the high pass filter is increased from 100 Hz to 1 kHz, the high pass filter may track the DC offset faster, which offers an improvement for the DC estimation to be completed within the preamble phase. However, the DC estimate transient is still too slow and does not finish converging by the time the preamble phase is over.

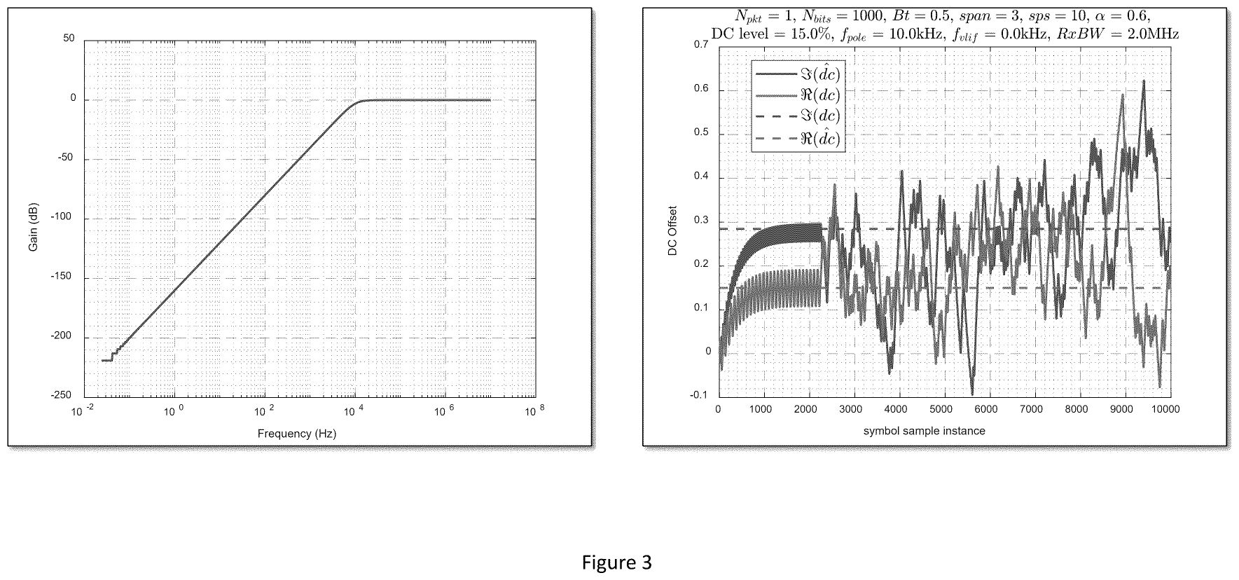

FIG. 3 shows graphs indicating performance of a high pass filter having a cutoff frequency of 10 kHz.

In the graph of the left hand side, it is shown that the high pass filter has a frequency response which effectively attenuates low frequency signals, including DC components. At frequencies below 100 Hz, the attenuation reaches −60 dB, which is practically zero. As the frequency approaches 0 Hz, the attenuation becomes infinite, ensuring perfect DC offset removal. At 10 kHz, the attenuation is about −3 dB, marking the corner frequency of the high pass filter.

Turning to the graph on the right hand side, it can be seen that when the pole frequency of the high pass filter is increased from 1 kHz to 10 kHz, the high pass filter may track the DC offset faster. During the preamble phase, the high pass filter effectively removes the unwanted DC component since the DC estimate converges quickly. However, when the transmission switches to the payload phase, the high pass filter also attenuates some of the desired signal content. The high pass filter appears unsettled in the payload phase due to having a very wide pole. During the payload phase, the DC estimate is now responding to and producing an estimate of the low frequency content of the wanted signal and hence this low frequency content of the signal is being removed, thereby compromising the overall performance of the system. It is effectively removing both the unwanted DC offset but also the wanted low frequency content of the payload signal.

In the example of a detection system, a high pass filter having a cutoff frequency of 10 kHz may result in suboptimal performance, especially in the case of a Viterbi detector, which requires a high signal-to-noise ratio (SNR) to achieve an acceptable same packet error rate (PER). It will be appreciated that the frequencies referred to above may be specific to a Viterbi application, and in general for other applications, they may scale up and down with the wanted signal bandwidth.

PER is a metric used to measure the reliability of data transmission in communication systems and it represents the ratio of the number of incorrectly received packets to the total number of transmitted packets. A PER of 50% indicates that half of the transmitted packets are received with errors. This could be due to various factors such as noise or interference in the communication channel.

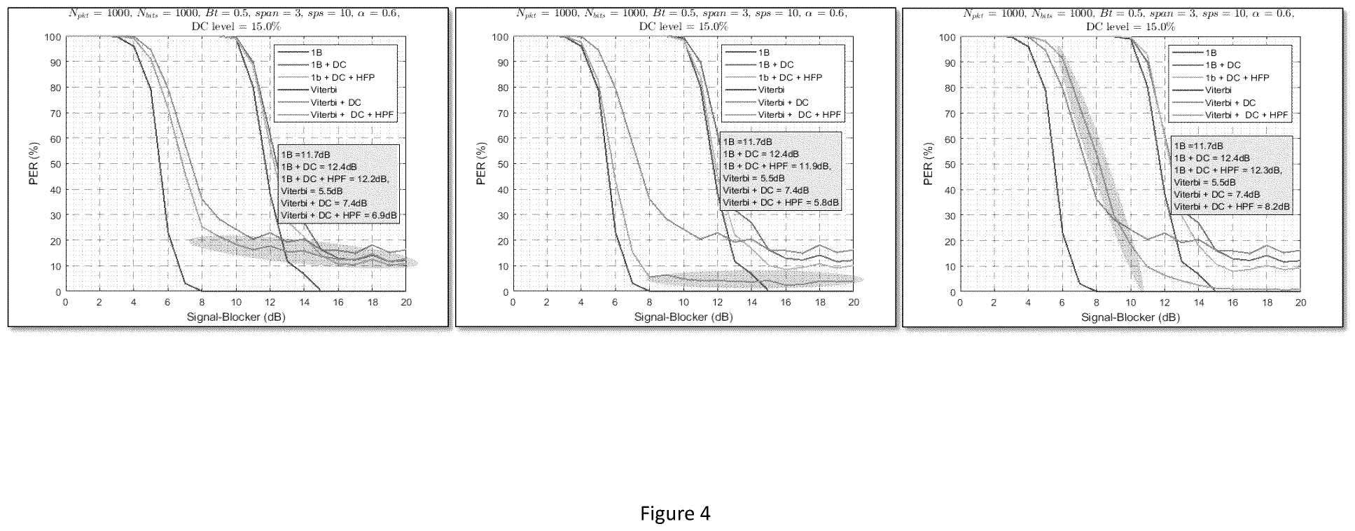

FIG. 4 shows graphs comparing PER performance of the high pass filter for different cutoff frequencies of FIGS. 1, 2 and 3. As it can be seen, DC offsets in the input signal can seriously degrade the PER of the high pass filter as well as introducing a higher PER noise floor, i.e. the background noise in the system.

In the graph on the left hand side, the performance of a high pass filter having a 100 Hz pole frequency, i.e. the cutoff frequency of the high pass filter is 100 Hz, is measured during the payload phase. The graph indicates that the PER performance of the high pass filter is affected by DC offsets, which leads to a higher noise floor and degraded PER for the same signal power. In other words, the signal power required to achieve the same PER, say 50%, must therefore be increased when there is a DC offset.

In the graph in the centre, the PER performance of a high pass filter having a 1 kHz pole frequency, i.e. the cutoff frequency of the high pass filter is 1 kHz, is measured during the payload phase. Compared with the graph for the 100 Hz pole, this graph also indicates that the performance of the high pass filter is affected by DC offsets, but the noise floor is reduced at this higher frequency.

In the graph on the right hand side, the PER performance of a high pass filter having a 10 kHz pole frequency, i.e. the cutoff frequency of the high pass filter is 10 kHz, is measured during the payload phase. Compared with the graphs for the 100 Hz and 1 kHz poles, this graph also indicates that the performance of the high pass filter is compromised because the high pass filter is now removing low frequency content of the wanted signal, but the noise floor is spread over a narrower signal power range. These examples illustrate that using a fixed pole high pass filter, it can be impossible to find an optimum or satisfactory trade off between attenuating the unwanted DC offset and not removing low frequency content of the wanted signal.

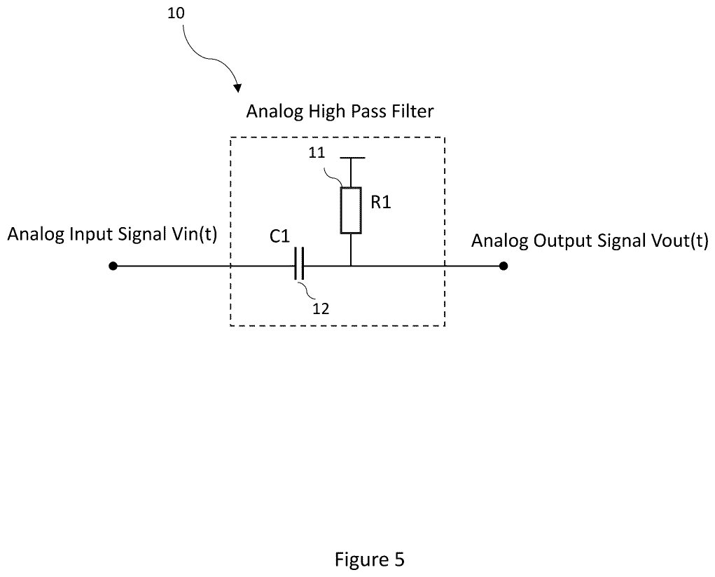

FIG. 5 is a block diagram that shows an analog high pass filter 10 for removing DC offsets from an analog input signal Vin (t). The analog high pass filter comprises resistor 11 and capacitor 12 components labeled as R1 and C1, which form the high pass filter circuit. The analog output signal is denoted as Vout (t). The analog high pass filter is designed to block low frequency signals, including DC components, while allowing higher frequency signals to pass through.

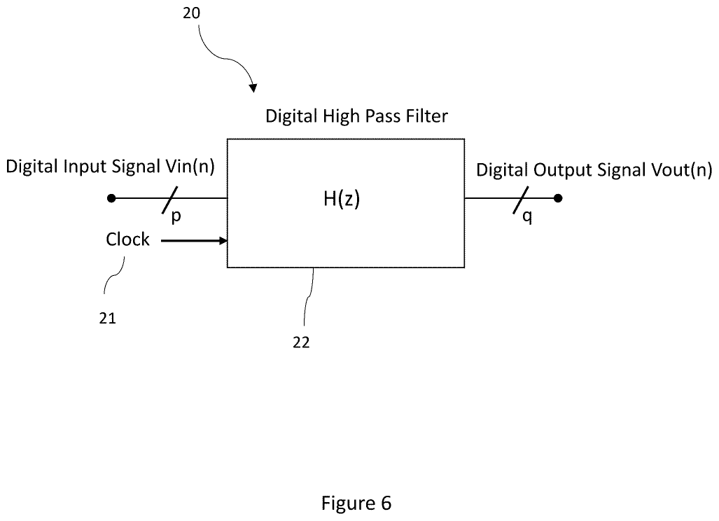

FIG. 6 is a block diagram that shows a digital high pass filter 20 for removing DC offsets from a digital input signal Vin (n). The digital high pass filter operates in the digital domain, its processing is synchronised using a clock signal from an input clock 21, and the input signal Vin (n) is high pass filtered by digital high pass filter block 22. The digital output signal is denoted as Vout (n). Similarly to the analog high pass filter 10, the digital high pass filter 20 is designed to eliminate low frequency components, including DC offsets, from the input signal.

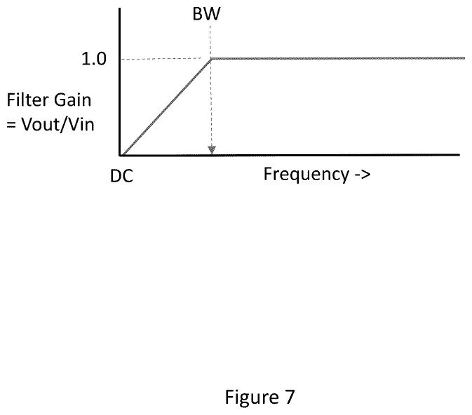

FIG. 7 shows the frequency response of both the analog high pass filter 10 of FIG. 5 and the digital high pass filter 20 of FIG. 6. FIG. 7 illustrates how the filter gain Vout/Vin varies with frequency. In particular, the graph shows that the bandwidth (BW) of the filter ends at the cutoff frequency of the high pass filter, which is determined by the pole frequency of the high pass filter i.e. the high pass filter effectively attenuates signals at DC (0 Hz) while allowing higher frequency signals above the cutoff frequency to pass through with minimal attenuation.

The analog high pass filter 10 of FIG. 5 and the digital high pass filter of FIG. 6 have a fixed pole frequency and a constant bandwidth as well as a constant transition and pass band. However, as described above, for a low frequency pole, the settling time for the DC offset can be quite long and this is problematic when the DC offset has not settled before the first phase of the input signal (for example, the preamble phase) has ended. In this situation, the DC offset may not be sufficiently attenuated by the high pass filter and so the output signal quality obtained in the second phase of the input signal (for example, the payload phase) may be compromised. In another situation, for a high frequency pole, the DC offset may have settled quickly and therefore be estimated accurately in the first phase (for example, the preamble phase), but the high frequency of the pole removes useful signal content of the output signal as well as the DC offset in the second phase of the input signal (for example, the payload phase).

Examples of the present disclosure allow for more than one pole frequency of the high pass filter to be selected, such that selecting a higher frequency pole of the high pass filter for the first phase of the input signal and a lower frequency pole of the high pass filter for the second phase of the input signal allows for optimal performance in both the first phase and the second phase of the input signal.

By dynamically profiling the bandwidth of the high pass filter for different phases of the input signal, this can significantly reduce the output settling time for a first phase, increase the proportion of useful signal content retrieved at the output, and minimise the amount of useful low frequency signal removed from the wanted signal.

The dynamic pole approach may be implemented by either analog or digital high pass filter circuitry since both define a pole frequency. In the following examples, block diagrams of both implementations are shown.

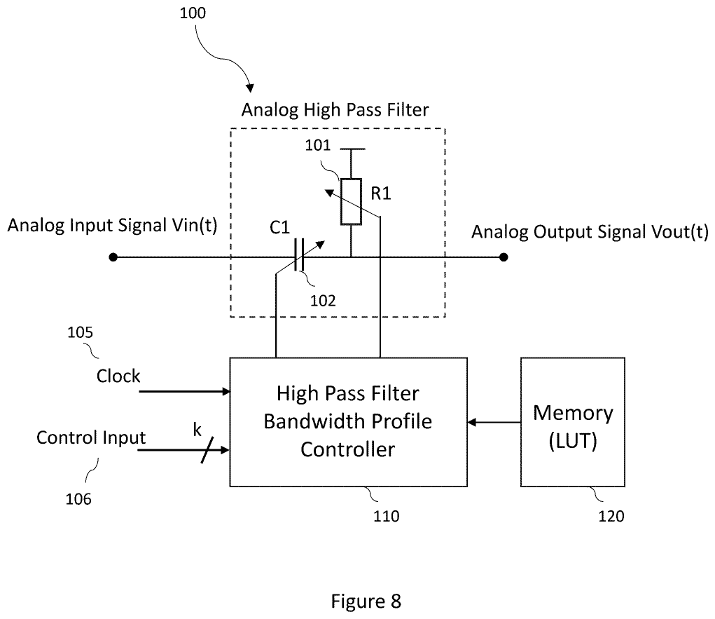

FIG. 8 is a block diagram that shows an analog high pass filter 100 for removing DC offsets from an analog input signal Vin (t) according to the present disclosure. The analog high pass filter comprises resistor 11 and capacitor 12 components labeled as R1 and C1, which form the high pass filter circuit. Additionally, it comprises a high pass filter bandwidth profile controller 110, which receives a clock signal from an input clock 105, a control signal from a control input 106 and a pole coefficient value from a memory 120 storing a LUT. The analog output signal is denoted as Vout (t). The analog high pass filter 100 is designed to block low frequency signals, including DC components, while allowing higher frequency signals to pass through.

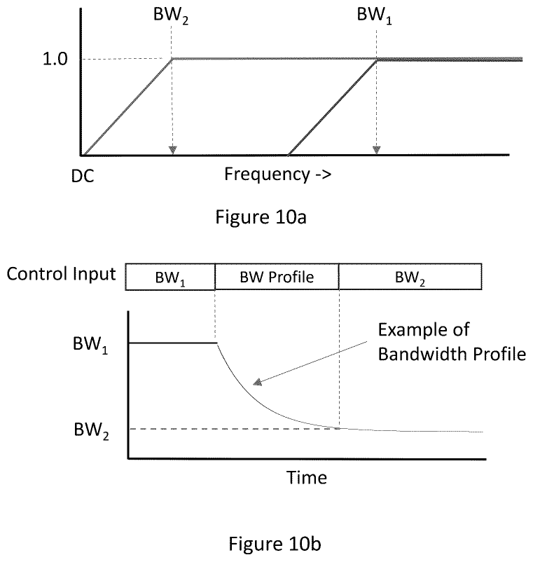

The resistor 11 may be a programmable resistor and/or the capacitor 12 may be a programmable capacitor. The resistor 11 and the capacitor 12 may form a single pole (1^{st} Order) analog passive high pass filter 100. However, higher order (2^{nd}, 3^{rd}, 4^{th} etc) analog passive or active high pass filters are also realizable as examples of the present disclosure. A controller may sequentially apply the Rs and Cs in a fashion so as to realise the pole profiling. The high pass filter 100 may typically be embedded in a generic analog signal chain. For a single pole analog high pass filter frequency response, the bandwidth (−3 dB frequency) of the high pass filter may be defined as follows and the dynamic nature of the single pole will be shown in FIG. 10:

$$\frac{1}{2 π ( R 1 C 1 )}$$

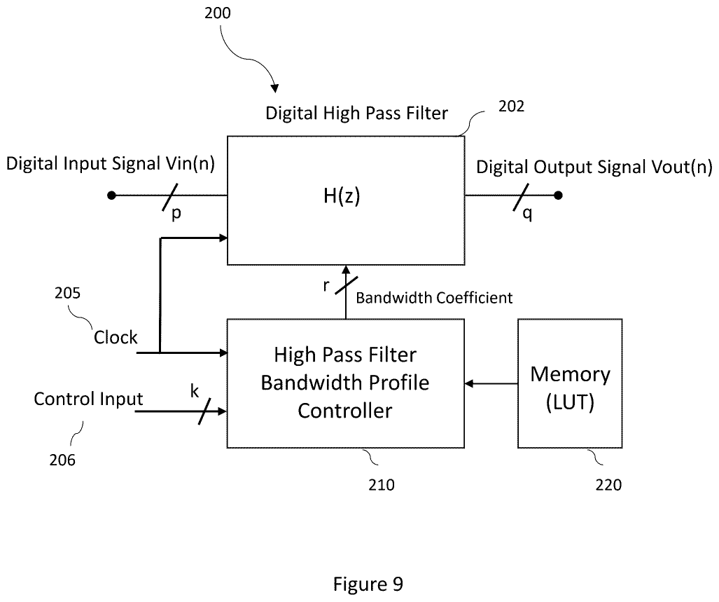

FIG. 9 is a block diagram that shows a digital high pass filter 200 for removing DC offsets from a digital input signal Vin (n) according to the present disclosure. The digital high pass filter 200 operates in the digital domain, and the input signal Vin (n) is high pass filtered by digital high pass filter block 202. Additionally, it comprises a high pass filter bandwidth profile controller 210, which receives a clock signal from an input clock 205, a control signal from a control input 206 and a pole coefficient value from a memory 220 storing a LUT. The digital output signal is denoted as Vout (n). Similarly to the analog high pass filter 100, the digital high pass filter 200 is designed to eliminate low frequency components, including DC offsets, from the input signal Vin (n).

The digital high pass filter block 202 may have a transfer function H (z), which may be an IIR or FIR realization of a single pole or multi pole digital high pass filter. The transfer function may typically be embedded in a generic digital signal chain. For a first order IIR high pass filter the pole coefficient is given by −e^{-2πf}^{ₚ}^{/F}^{ₛ}, where fₚ is the pole frequency and Fₛ is the sampling rate. When fₚ is 0 Hz, the pole coefficient is 1 and as fₚ tends towards infinity, the pole coefficient-->0.

FIG. 10 shows the frequency response of both the analog high pass filter 100 of FIG. 8 and the digital high pass filter 200 of FIG. 9. FIG. 10(a) illustrates how the filter gain Vout/Vin varies with frequency. In particular, the graph shows examples of two different frequency responses that represent the upper bandwidth (BW1) and lower bandwidth (BW2) settings of the high pass filter. Each of the frequency responses attenuate signals at DC (0 Hz) while allowing higher frequency signals to pass through with minimal attenuation. The control input is used to configure the state of the bandwidth profile controller 210 in FIG. 9.

As shown in FIG. 10(b), the control input initially defines a constant, high frequency bandwidth BW1 to be applied to the high pass filter.

After a predetermined time (which may be initiated from an external timing signal such as a system wake-up event or by observing some characteristics of the high pass filter's input signal or from a system timing control signal), the control input configures the bandwidth profile controller 210 in FIG. 9 to initiate time-profiling of the high pass filter's bandwidth according to the contents of the Memory LUT 220.

The bandwidth profiling may preferably be exponentially shaped between bandwidths BW1 and BW2 over a predetermined time duration—as illustrated in FIG. 10(b). However, it can also be configured to support any nonlinear or linear time based bandwidth profile, as defined by the contents of the LUT Memory.

When the high pass filter bandwidth profiling is complete and it has reached the lower bandwidth BW2, the control input configures the bandwidth profile controller 210 to retain the lower bandwidth BW2 for a specified period.

By initiating the high pass filters bandwidth profile at a specific time, that corresponds to the arrival of an input signal at the high pass filter's input, a significant reduction in settling time of the high pass filter output can be obtained, compared to the case where a high pass filter is employed with a fixed lower bandwidth setting, such as BW1.

After a further time delay period (not shown) the control input will reset the Bandwidth Profile controller 210 to re-apply the higher bandwidth BW1, in preparation for the arrival of a new input signal at the input to the high pass filter.

By adjusting the pole coefficient input into the high pass filter, the high pass filter can be tuned to pass a wider range of higher frequencies while effectively attenuating lower frequencies, including the DC component. This dynamic adjustment is important for achieving very low latency, very low power and optimal performance in different phases of signal processing, including a first phase in which a DC offset of the input signal is estimated, and a subsequent second phase in which a desired signal that has the DC offset removed may be output.

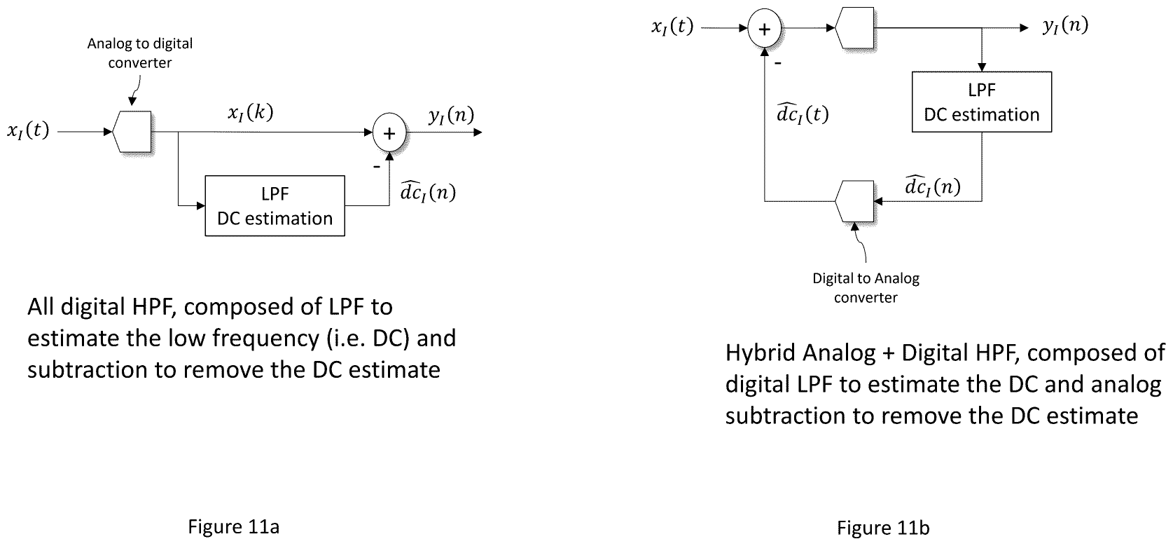

FIG. 11a provides an example of a digital high pass filter for use in methods and apparatuses of the present disclosure. This high pass filter is composed of a low-pass filter (LPF) to estimate the low frequency (i.e., DC) and a subtraction process to remove the DC estimate.

FIG. 11b provides an example of a hybrid analog and digital high pass filter for use in methods and apparatuses of the present disclosure. This high pass filter combines a digital LPF to estimate the DC and an analog subtraction process to remove the DC estimate.

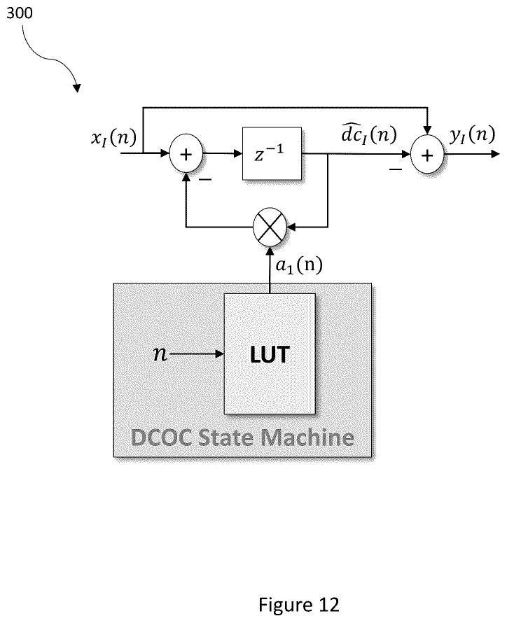

FIG. 12 shows an example implementation of the present disclosure for a digital system such as a communications system. The block diagram of FIG. 12 shows a high pass filter 300 that may be used in a Viterbi detector for detecting a digital input signal x_{I}(n) and producing a filtered signal y_{I}(n) The Viterbi detector operates in the digital domain and includes a DCOC (DC Offset Correction) state machine. The input signal x_{I}(n) is processed by the DCOC state machine to remove DC offsets. The state machine receives a pole coefficient a₁(n), which is used in a feedback loop to shape the frequency response of the high pass filter and produce a corrected output signal y_{I}(n). The Viterbi detector is designed to eliminate low-frequency components, including DC offsets, from the input signal x_{I}(n), thus ensuring accurate detection of the transmitted data in the input signal. The output of the high pass filter may be expressed as:

y_{I}(n)=x_{I}(n)− [symbol] (n)

This equation shows how a current corrected output signal y_{I}(n) is the input x_{I}(n) with the estimated DC [symbol] (n) subtracted off. . . . The estimated DC [symbol] (n) is the low pass filtered of the input.

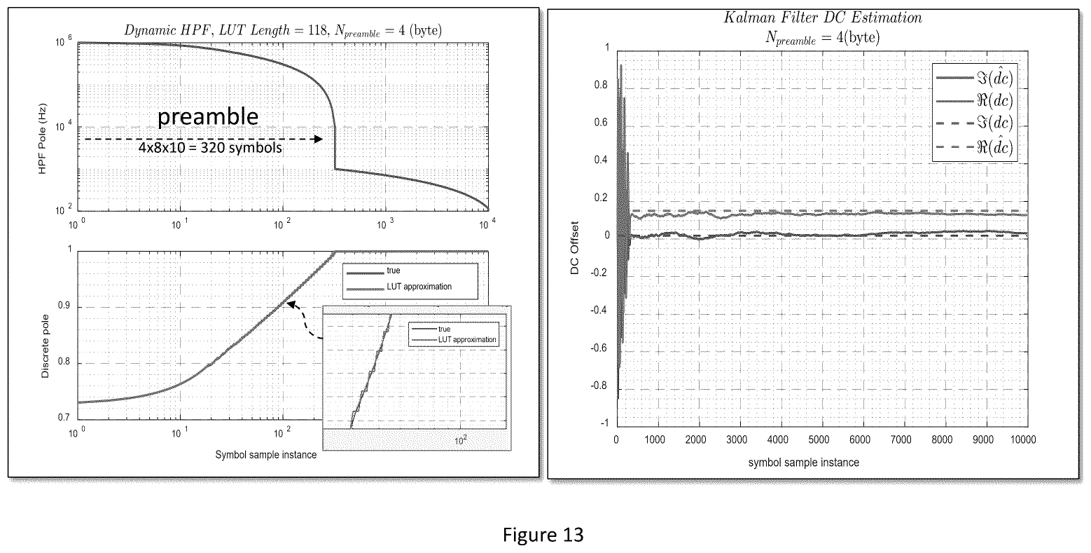

In the example of FIG. 12, the high pass filter pole coefficients may be dynamically varied over the transmission of a packet of information. This is shown graphically in FIG. 13. During a preamble phase, the pole frequency may be ‘large’ (for example, 1 MHz to 10 kHz) for ‘fast’ DC estimation, then after the preamble phase, the pole may be slowed down (for example, 1 kHz to 100 Hz) for finer DC offset correction and in order to limit attenuation of low frequency signal content. For a first order high pass filter, this may be represented as:

$$\frac{1 - {z}^{- 1}}{1 + {α}_{1} {z}^{- 1}}$$

The pole may be zero at DC and a discrete pole at other frequencies of:

$$z = - {a}_{1} = {e}^{- \frac{2 π {f}_{pole}}{{F}_{s}}} ,$$

wherein fₚₒₗₑ is the pole frequency and Fₛ is the sample rate

The corrected output signal may be expressed as follows:

$$y ( n ) = x ( n ) - x ( n - 1 ) - {a}_{1} ( n ) y ( n - 1 ) , {a}_{1} = - {e}^{- 2 π \frac{{f}_{pole} ( n )}{{F}_{s}}}$$

In the left hand side graph of FIG. 13, it can be seen that the preamble phase lasts for 320 symbols before the payload phase begins. During the preamble phase, a high-frequency pole (for example, 1 MHZ) may be used to quickly track the DC offset. As the preamble phase progresses, the pole frequency is gradually reduced to a lower frequency (for example, 100 Hz) when the payload phase begins, minimizing the attenuation of the desired signal. The pole frequency is also shown to gradually reduce during the payload phase. This dynamic adjustment ensures fast DC acquisition and accurate signal processing.

The dynamic adjustment may involve using a lookup table to find a pole coefficient for a particular time parameter and using a state machine to adjust the pole frequency over time. This approach allows the high pass filter to adapt to different phases of signal processing, thus achieving optimal performance for each phase.

In the right hand side graph of FIG. 13, it can be seen that DC offset estimation for both the in-phase, I, component and quadrature, Q, component of the input signal tracks well.

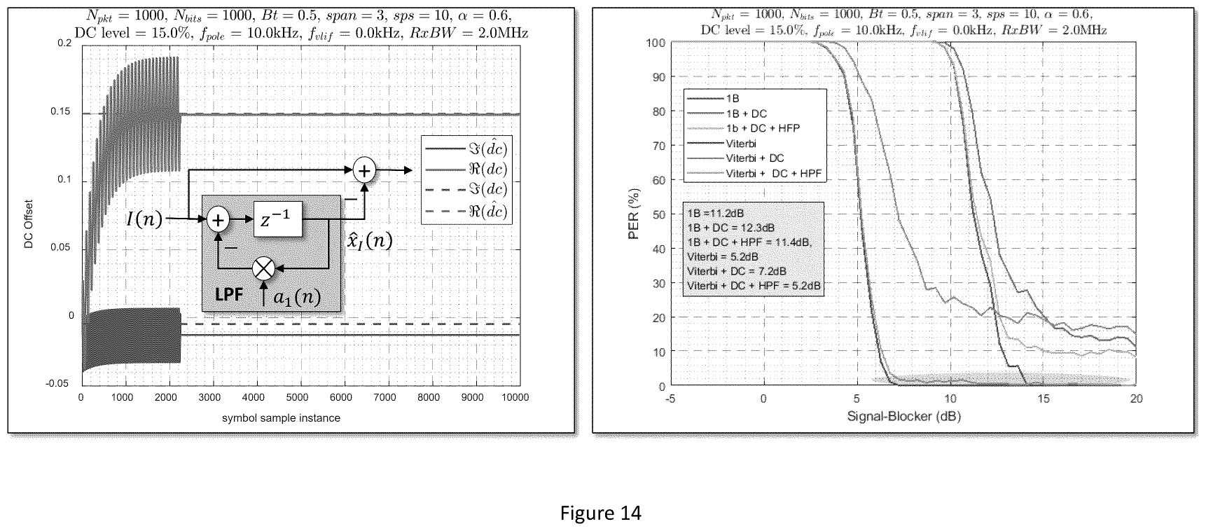

FIG. 14 shows the performance of a high pass filter used in a Viterbi detector.

In the left hand side graph of FIG. 14, it can be seen that the input signal is applied for 10,000 symbols. A pole coefficient may be selected for a time parameter, for example, for one or more symbol sample instances, whereby the pole coefficient may be expressed as:

$${a}_{1} ( n ) = - {e}^{- \frac{2 π {f}_{pole} ( n )}{{F}_{s}}}$$

Initially, a ‘fast’ pole (10 kHz) is selected during the preamble phase. Then, a ‘slow’ (˜100 Hz) pole is selected during last fundamental frequency cycle of the preamble phase. Finally, a ‘slower’ or 0 Hz pole is selected for the payload phase, which occurs after preamble phase.

In the right hand side graph of FIG. 14, the wanted power to interference power ratio is shown along the x-axis in dB and PER is shown along the y-axis. The signal power to interference power ratio (SIR) in dB required for 50% PER for various types of detectors are shown. The dB value indicates that the input signal must be a certain amount above the noise level for half of the packets to be correctly received.

For a one-bit detector, the dark blue line represents an ideal one-bit detector with no DC offset. When a DC offset is added, as indicated by the red line, the required signal power must be increased by approximately 0.5 dB to achieve the same packet error rate. However, when a high pass filter is applied to the input signal, then the DC offset is removed and brings the signal power back down by approximately 0.5 dB to achieve the same packet error rate.

For a Viterbi detector, where the ideal performance requires 5.5 dB of SNR for 50% packet accuracy, adding a DC offset (without the dynamic high pass filter) increases the required SNR by 2 dB, and using the high pass filter allows significant recovery of the original performance, bringing the signal power back down by approximately 2 dB to achieve the same packet error rate.

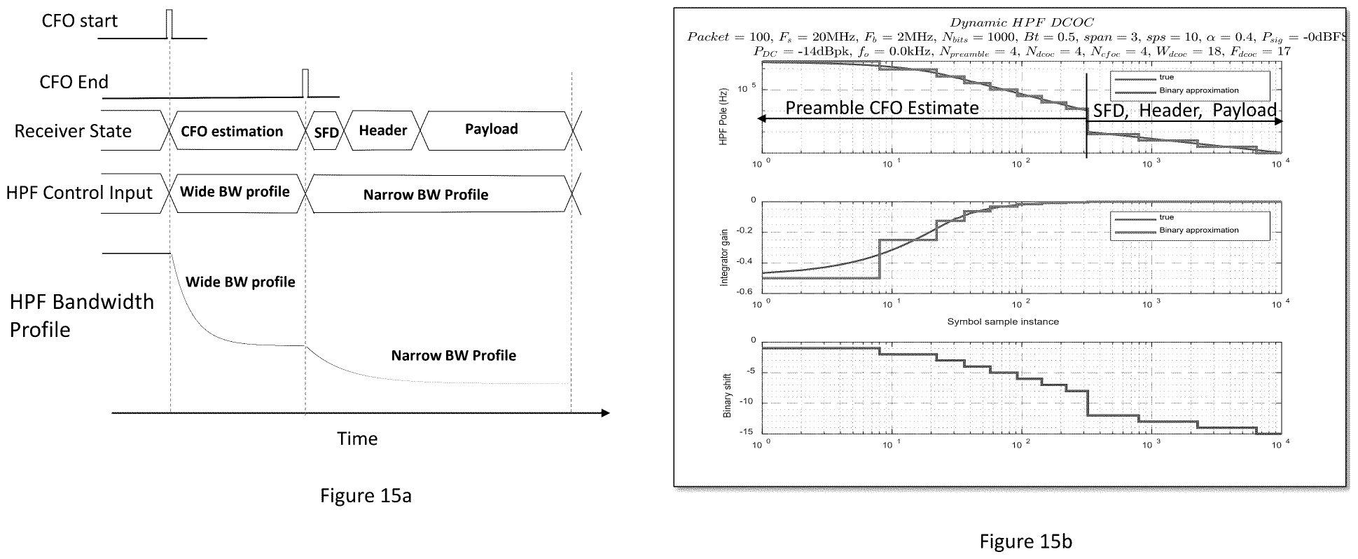

FIGS. 15a and 15b show how pole coefficient profiles may be determined using a state machine. It shows that a wide bandwidth profile commences, and high pass filter resets a programmable time prior to end of preamble, for example, at the carrier frequency offset (CFO) start. When the wide bandwidth profile terminates, and a low bandwidth profile commences at end of preamble, for example, at the CFO end. Then, the low band profile terminates at the end of the payload phase.

Towards the end of the preamble phase, at the onset of CFO stage, the state machine commences reading out the pole coefficient from a Look UP Table (LUT). Initially the coefficient corresponds to a wide BW pole (for example, 10 MHz). During the CFO phase, the state machine reads out successive pole coefficient on a periodic time based corresponding to successively lower pole bandwidth values. At the end of the preamble, marked by the end of the CFO phase and the start of the Start-Frame-Header (SFD), the machine reads out the last wide BW pole coefficients and transitions into reading out lower bandwidth pole coefficients. Henceforth, the state machine reads out progressively lower pole bandwidth coefficients until the end of the payload. At the end of the payload phase, the state machine is reset and primed for the commencement of the next preamble.

FIGS. 15a and 15b show two sequential profiles, specifically a wide bandwidth profile and a narrow bandwidth profile. The main benefits of this dual profiling approach are improved carrier frequency offset estimation (the wide bandwidth profile is used for coarse carrier frequency offset estimation, while the narrow bandwidth profile is used for fine carrier frequency offset estimation), enhanced signal processing (the dual profiling allows the system to better handle variations in the input signal, leading to more robust and reliable signal processing), and optimised performance of the high pass filter (the dual profiling approach allows for optimized performance by selecting the appropriate profile based on the specific requirements of each phase of the signal processing).

The control inputs of FIG. 15a may be those shown in FIG. 10. The control inputs make the pole profile to be wide, narrow or fixed, for example. In this case, the initial bandwidth (BW1) may be fixed, and the final bandwidth (BW2) may also be fixed, as per FIG. 10.

In FIG. 15a, exponential high pass filter bandwidth profiles are shown, while in FIG. 15b a binary weighted approximation is employed for the high pass filter bandwidth profiles. However, it will be appreciated that any linear or non-linear profile may also be used within the scope of the present disclosure.

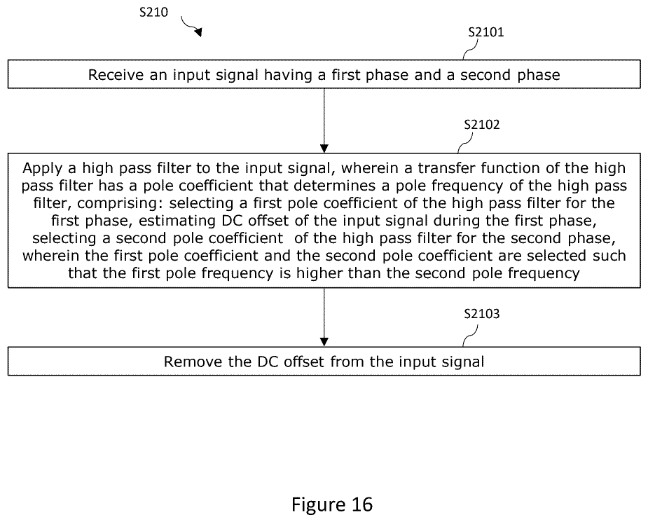

FIG. 16 represents example method steps S210 according to an aspect of the present disclosure. In general, at step S2101, an input signal having a first phase and a second phase is received. At step S2102, a high pass filter is applied to the input signal, wherein a transfer function of the high pass filter has a pole coefficient that determines a pole frequency of the high pass filter, comprising: selecting a first pole coefficient of the high pass filter for the first phase, estimating DC offset of the input signal during the first phase, selecting a second pole coefficient of the high pass filter for the second phase, wherein the first pole coefficient and the second pole coefficient are selected such that the first pole frequency is higher than the second pole frequency. Finally, at step S210, the DC offset is removed from the input signal.

The skilled person will readily appreciate that various alterations or modifications may be made to the above-described aspects of the disclosure without departing from the scope of the disclosure. For example, features of two or more of the above examples may be combined and still fall within the scope of the present disclosure.

### Numbered Aspects

By way of non-limiting example, some aspects of the disclosure are set out in the following numbered clauses.
Numbered Clause 1. A method of removing a DC offset from an input signal, the method comprising:
   receiving the input signal having a first phase and a second phase;
   applying a high pass filter to the input signal, wherein a transfer function of the high pass filter has a pole coefficient that determines a pole frequency of the high pass filter, comprising:
      selecting a first pole coefficient of the high pass filter for the first phase,
      estimating DC offset of the input signal during the first phase, and
      selecting a second pole coefficient of the high pass filter for the second phase, wherein the first pole coefficient and the second pole coefficient are selected such that the first pole frequency is higher than the second pole frequency; and
   removing the DC offset from the input signal.
Numbered Clause 2. The method according to Numbered Clause 1, further comprising using a look up table to select the pole coefficient of the high pass filter.
Numbered Clause 3. The method according to Numbered Clause 2, wherein using a look up table to determine the pole coefficient of the high pass filter comprises selecting the pole coefficient based on a time parameter.
Numbered Clause 4. The method according to Numbered Clause 3, wherein the time parameter is a time instant, a time index or a time interval.
Numbered Clause 5. The method of any preceding Numbered Clause, wherein the pole coefficient is a value between 0 and 1.
Numbered Clause 6. The method according to any preceding Numbered Clause, wherein the first phase comprises a predetermined duration, and selecting the first pole coefficient for the first phase comprises selecting the first pole coefficient such that estimating the DC offset is completed within the predetermined duration.
Numbered Clause 7. The method according to Numbered Clause 6, wherein the predetermined duration comprises a predetermined number of symbols.
Numbered Clause 8. The method according to any of Numbered Clauses 2 to 7, further comprising dynamically adjusting the pole coefficient of the high pass filter using the look-up table.
Numbered Clause 9. The method according to Numbered Clause 8, further comprising dynamically adjusting the pole coefficient from the first pole coefficient to the second pole coefficient.
Numbered Clause 10. The method according to Numbered Clause 8 or 9, further comprising dynamically adjusting the first pole coefficient so as to decrease the pole frequency during the first phase.
Numbered Clause 11. The method according to Numbered Clause 10, wherein dynamically adjusting the first pole coefficient comprises dynamically lowering the first pole coefficient exponentially.
Numbered Clause 12. The method according to any of Numbered Clauses 8 to 11, further comprising dynamically adjusting the second pole coefficient so as to decrease the pole frequency during the second phase.
Numbered Clause 13. The method according to Numbered Clause 12, wherein dynamically adjusting the second pole coefficient comprises dynamically lowering the second pole coefficient exponentially.
Numbered Clause 14. The method according to any preceding Numbered Clause, further comprising using at least one of a state machine, a logic sequencer, a timing controller and a systems controller to control the selection of the pole coefficient.
Numbered Clause 15. The method according to any preceding Numbered Clause, wherein estimating the DC offset comprises low pass filtering the input signal, and the method further comprises removing the DC offset from the input signal by subtracting the estimated DC offset from the input signal.
Numbered Clause 16. The method according to Numbered Clause 15, further comprising using a feedback loop to update the estimated DC offset based on a pole coefficient of the high pass filter.
Numbered Clause 17. The method according to any preceding Numbered Clause, wherein an output signal of the high pass filter is a difference between the input signal and a previous input signal minus the pole coefficient multiplied by a previous output signal.
Numbered Clause 18. The method according to any preceding Numbered Clause, wherein selecting a first pole coefficient comprises selecting a first pole coefficient such that a first pole frequency is between 1 MHz and 10 kHz and/or wherein selecting a second pole coefficient comprises selecting a second pole coefficient such that the second pole frequency is between 1 kHz and 100 Hz.
Numbered Clause 19. The method according to any preceding Numbered Clause, wherein the first phase is preamble phase and the second phase is a payload phase.
Numbered Clause 20. An apparatus for removing a DC offset from an input signal, the apparatus comprising:
   a high pass filter, configured to:
      receive an input signal having a first phase and a second phase;
      apply a high pass filter to the input signal, wherein a transfer function of the high pass filter has a pole coefficient that determines a pole frequency of the high pass filter, comprising:
         selecting a first pole coefficient of the high pass filter for the preamble phase,
         estimating DC offset of the input signal during the first phase, and
         selecting a second pole coefficient of the high pass filter for the second phase, wherein the first pole coefficient and the second pole coefficient are selected such that the first pole frequency is higher than the second pole frequency; and
      remove the DC offset from the input signal.
Numbered Clause 21. The apparatus according to Numbered Clause 20, wherein the high pass filter has a time varying pole frequency.
Numbered Clause 22. The apparatus according to Numbered Clause 20 or 21, wherein the high pass filter is a first order high pass filter or a higher order high pass filter.
Numbered Clause 23. The apparatus according to any of Numbered Clauses 13 to 15, wherein the high pass filter comprises a differentiator and a low pass filter.
Numbered Clause 24. The apparatus according to any of Numbered Clauses 13 to 15, wherein the high pass filter comprises a leaky integrator.
Numbered Clause 25. The apparatus according to any of Numbered Clauses 13 to 16, further comprising a memory device configured to store a look up table.
Numbered Clause 26. The apparatus according to Numbered Clause 25, wherein an input to the look up table comprises a time parameter and an output of the look up table comprises the pole coefficient.
Numbered Clause 27. The apparatus according to any of Numbered Clauses 20 to 26, further comprising at least one of a state machine, a logic sequencer, a timing controller and a systems controller.
Numbered Clause 28. The apparatus according to Numbered Clause 27, wherein the state machine is configured to generate a pulse indicating the start of the first phase and configured to generate a pulse indicating the start of the second phase.
Numbered Clause 29. The apparatus according to Numbered Clause 27 or 28, wherein the state machine is configured to generate a timeslot for the first phase and generate a timeslot for the second phase.

1. A method of removing a DC offset from an input signal, the method comprising:
receiving the input signal having a first phase and a second phase;
applying a high pass filter to the input signal, wherein a transfer function of the high pass filter has a pole coefficient that determines a pole frequency of the high pass filter, comprising:
selecting a first pole coefficient of the high pass filter for the first phase,
estimating DC offset of the input signal during the first phase, and
selecting a second pole coefficient of the high pass filter for the second phase, wherein the first pole coefficient and the second pole coefficient are selected such that the first pole frequency is higher than the second pole frequency; and
removing the DC offset from the input signal.

2. The method according to claim 1, further comprising using a look up table to select the pole coefficient of the high pass filter.

3. The method according to claim 2, wherein using a look up table to determine the pole coefficient of the high pass filter comprises selecting the pole coefficient based on a time parameter, preferably wherein the time parameter is a time instant, a time index or a time interval.

4. The method of claim 1, wherein the pole coefficient is a value between 0 and 1.

5. The method according to claim 1, wherein the first phase comprises a predetermined duration, and selecting the first pole coefficient for the first phase comprises selecting the first pole coefficient such that estimating the DC offset is completed within the predetermined duration.

6. The method according to claim 2, further comprising dynamically adjusting the pole coefficient of the high pass filter using the look-up table.

7. The method according to claim 6, further comprising dynamically adjusting the pole coefficient from the first pole coefficient to the second pole coefficient.

8. The method according to claim 6, further comprising dynamically adjusting the first pole coefficient so as to decrease the pole frequency during the first phase, and preferably wherein dynamically adjusting the first pole coefficient comprises dynamically lowering the first pole coefficient exponentially.

9. The method according to claim 6, further comprising dynamically adjusting the second pole coefficient so as to decrease the pole frequency during the second phase, and preferably wherein dynamically adjusting the second pole coefficient comprises dynamically lowering the second pole coefficient exponentially.

10. The method according to claim 1, further comprising using at least one of a state machine, a logic sequencer, a timing controller and a systems controller to control the selection of the pole coefficient.

11. The method according to claim 1, wherein estimating the DC offset comprises low pass filtering the input signal, and the method further comprises removing the DC offset from the input signal by subtracting the estimated DC offset from the input signal.

12. The method according to claim 1, wherein the first phase is preamble phase and the second phase is a payload phase.

13. An apparatus for removing a DC offset from an input signal, the apparatus comprising:
a high pass filter, configured to:
receive an input signal having a first phase and a second phase;
apply a high pass filter to the input signal, wherein a transfer function of the high pass filter has a pole coefficient that determines a pole frequency of the high pass filter, comprising:
selecting a first pole coefficient of the high pass filter for the preamble phase,
estimating DC offset of the input signal during the first phase, and
selecting a second pole coefficient of the high pass filter for the second phase, wherein the first pole coefficient and the second pole coefficient are selected such that the first pole frequency is higher than the second pole frequency; and
removing the DC offset from the input signal.

14. The apparatus according to claim 13, wherein the high pass filter has a time varying pole frequency.

15. The apparatus according to claim 13, wherein the high pass filter is a first order high pass filter or a higher order high pass filter.

16. The apparatus according to claim 13, wherein the high pass filter comprises at least one of the following:
a differentiator and a low pass filter; and
a leaky integrator.

17. The apparatus according to claim 13, further comprising a memory device configured to store a look up table.

18. The apparatus according to claim 17, wherein an input to the look up table comprises a time parameter and an output of the look up table comprises the pole coefficient.

19. The apparatus according to claim 13, further comprising at least one of a state machine, a logic sequencer, a timing controller and a systems controller.

20. The apparatus according to claim 19, wherein the state machine is configured to generate a pulse indicating the start of the first phase and configured to generate a pulse indicating the start of the second phase and/or wherein the state machine is configured to generate a timeslot for the first phase and generate a timeslot for the second phase.
